(19) United States
(12) Patent Application Publication
(10) Pub. No.: US 2025/0063839 A1
(43) Pub. Date: Feb. 20, 2025

(54) IMAGING DEVICE AND ELECTRONIC DEVICE

(71) Applicant: SONY SEMICONDUCTOR SOLUTIONS CORPORATION, KANAGAWA (JP)

(72) Inventors: ISAYA KITAMURA, KANAGAWA (JP); YUKI MIYANAMI, KANAGAWA (JP); CHIGUSA YAMANE, KANAGAWA (JP); TORU MARUYAMA, KANAGAWA (JP); TAKASHI KOJIMA, KANAGAWA (JP)

(21) Appl. No.: 18/722,580

(22) PCT Filed: Dec. 15, 2022
(86) PCT No.: PCT/JP2022/046141

§ 371 Date: Jun. 20, 2024

(30) Foreign Application Priority Data
Dec. 28, 2021 (JP) 2021-214465

(51) Int. Cl. H01L 27/146

(52) U.S. Cl. CPC H01L 27/1462; H01L 27/14623; H01L 27/1463; H01L 27/14683

(57) ABSTRACT

The present technique relates to an imaging device and an electronic device that can further suppress the occurrence of white spots and dark current.

The imaging device includes: a photoelectric conversion region including a first semiconductor region containing a first impurity and a second semiconductor region containing a second impurity; and a layer region including at least a first layer containing a high concentration of the first impurity and a second layer made of a predetermined material on a light incident surface side of the photoelectric conversion region. The imaging device further includes a pixel array part including the photoelectric conversion region disposed therein in an array form; and a pixel peripheral part including a processing unit that is disposed therein and processes a signal from the pixel array part. The pixel peripheral part is provided with a layer region not including the first layer. The present technique is applicable to, for example, an imaging device such as an image sensor.

### TECHNICAL FIELD

The present technique relates to an imaging device and an electronic device, and relates to, for example, an imaging device and an electronic device that can suppress image quality degradation caused by the occurrence of white spots.

### BACKGROUND ART

In the prior art, for example, imaging elements such as CCD (Charge Coupled Device) or CMOS (Complementary Metal Oxide Semiconductor) image sensors are used in electronic devices having imaging functions, for example, digital still cameras or digital video cameras (for example, see PTL 1).

PTL 2 proposes a structure that prevents weakening of pinning of charge, the occurrence of white spots, and the occurrence of dark current in an image sensor.

### CITATION LIST

### Patent Literature

### PTL 1

JP 2021-15957A

### PTL 2

JP 2018-148116A

### SUMMARY

### Technical Problem

There are demands for the prevention of weakening of pinning and for further suppression of the occurrence of white spots and dark current.

The present technique has been made in view of such circumstances and is configured to suppress the occurrence of white spots and dark current.

### Solution to Problem

An imaging device according to an aspect of the present technique is an imaging device including: a photoelectric conversion region including a first semiconductor region containing a first impurity and a second semiconductor region containing a second impurity; and a layer region including at least a first layer containing a high concentration of the first impurity, and a second layer made of a predetermined material on a light incident surface side of the photoelectric conversion region.

An electronic device according to an aspect of the present technique is an electronic device including: an imaging device; and a processing unit, the imaging device including a photoelectric conversion region including a first semiconductor region containing a first impurity and a second semiconductor region containing a second impurity, the imaging device further including a layer region including at least a first layer containing a high concentration of the first impurity, and a second layer made of a predetermined material on a light incident surface side of the photoelectric conversion region, and the processing unit being configured to process a signal from the imaging device.

Provided in an imaging device according to an aspect of the present technique is a photoelectric conversion region including a first semiconductor region containing a first impurity and a second semiconductor region containing a second impurity; and a layer region including at least a first layer containing a high concentration of the first impurity, and a second layer made of a predetermined material on a light incident surface side of the photoelectric conversion region.

An electronic device according to an aspect of the present technique is configured with the imaging device.

The imaging device and the electronic device may be independent devices or internal blocks constituting a single device.

### BRIEF DESCRIPTION OF DRAWINGS

FIG. 1 illustrates a schematic configuration of an imaging device according to the present disclosure.

FIG. 2 is an explanatory drawing of a pixel and a pixel peripheral part.

FIG. 3 illustrates an exemplary sectional configuration of a pixel according to a first embodiment.

FIG. 4 is an explanatory drawing of a first manufacturing process of the pixel.

FIG. 5 is an explanatory drawing of the first manufacturing process of the pixel.

FIG. 6 is an explanatory drawing of the first manufacturing process of the pixel.

FIG. 7 is an explanatory drawing of a second manufacturing process of the pixel.

FIG. 8 is an explanatory drawing of the second manufacturing process of the pixel.

FIG. 9 is an explanatory drawing of the second manufacturing process of the pixel.

FIG. 10 illustrates an exemplary sectional configuration of a pixel according to a second embodiment.

FIG. 11 illustrates an exemplary sectional configuration of a pixel according to a third embodiment.

FIG. 12 illustrates an exemplary sectional configuration of a pixel according to a fourth embodiment.

FIG. 13 illustrates an exemplary sectional configuration of a pixel according to a fifth embodiment.

FIG. 14 illustrates another exemplary sectional configuration of the pixel according to the fifth embodiment.

FIG. 15 illustrates an exemplary sectional configuration of a pixel according to a sixth embodiment.

FIG. 16 illustrates an exemplary sectional configuration of a pixel according to a seventh embodiment.

FIG. 17 illustrates an exemplary sectional configuration of a pixel according to an eighth embodiment.

FIG. 18 is an explanatory drawing illustrating the configuration of an electronic device.

FIG. 19 is a block diagram illustrating an example of a schematic configuration of a vehicle control system.

FIG. 20 is an explanatory drawing illustrating an example of installation positions of a vehicle external information detection unit and imaging units.

### DESCRIPTION OF EMBODIMENTS

Modes for carrying out the present technique (hereinafter referred to as embodiments) will be described below.

### Schematic Configuration Example of Imaging Device

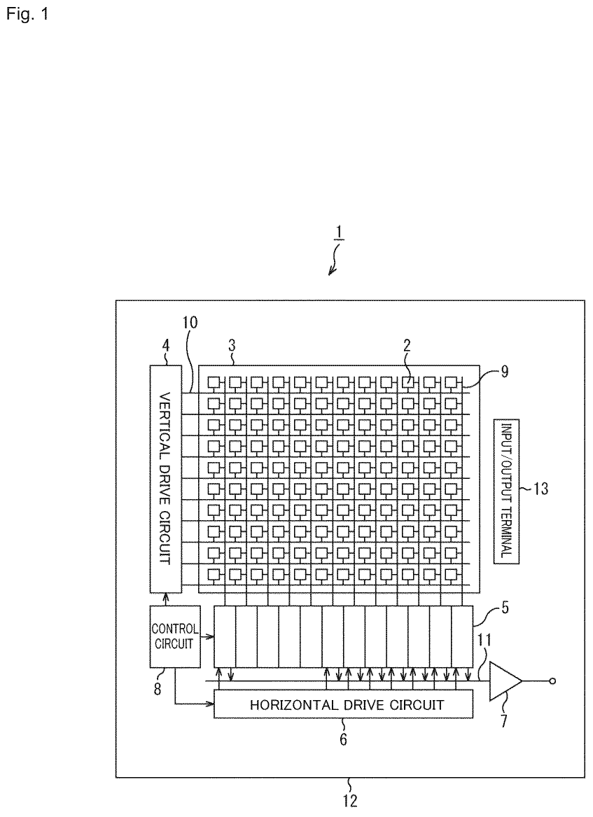

FIG. 1 illustrates a schematic configuration of an imaging device according to the present disclosure.

An imaging device 1 in FIG. 1 is configured with a pixel array part 3 including pixels 2 arranged in a two-dimensional array on a semiconductor substrate 12, in which, for example, silicon (Si) is used as a semiconductor, and a peripheral circuit part around the pixel array part. The peripheral circuit unit includes a vertical drive circuit 4, column signal processing circuits 5, a horizontal drive circuit 6, an output circuit 7, and a control circuit 8.

The pixel 2 includes a photodiode as a photoelectric conversion element and a plurality of pixel transistors. The plurality of pixel transistors are configured with, for example, four MOS transistors: a transfer transistor, a selection transistor, a reset transistor, and an amplification transistor.

The pixel 2 can also have a shared pixel structure. The pixel shared structure is configured with a plurality of photodiodes, a plurality of transfer transistors, a floating diffusion (floating diffusion region) to be shared, and other pixel transistors to be shared one by one. In other words, the shared pixel is configured such that the photodiodes and the transfer transistors configuring a plurality of unit pixels share each one other pixel transistor.

The control circuit 8 receives input clocks and data for providing an instruction about an operation mode or the like and outputs data such as internal information about the imaging device 1. In other words, in response to a vertical synchronizing signal, a horizontal synchronizing signal, and a master clock signal, the control circuit 8 generates clock signals or control signals as standards for operations of the vertical drive circuit 4, the column signal processing circuit 5, and the horizontal drive circuit 6 or the like. The control circuit 8 then outputs the generated clock signals or control signals to the vertical drive circuit 4, the column signal processing circuits 5, and the horizontal drive circuit 6 or the like.

The vertical drive circuit 4 is configured with, for example, a shift register, selects a pixel drive wiring 10, supplies a pulse for driving the pixels 2 to the selected pixel drive wiring 10, and drives the pixels 2 for each row. In other words, the vertical drive circuit 4 selectively scans the pixels 2 sequentially for each row in the vertical direction in the pixel array part 3 and supplies a pixel signal to the column signal processing circuits 5 through vertical signal lines 9, the pixel signal being supplied on the basis of a signal charge generated according to the amount of received light in the photoelectric conversion regions of the pixels 2.

The column signal processing circuit 5 is arranged for each column of the pixels 2 and performs, for each pixel column, signal processing such as noise reduction on a signal output from the pixel 2 of one row. For example, the column signal processing circuit 5 performs signal processing such as CDS (Correlated Double Sampling) for removing fixed pattern noise unique to the pixel and AD conversion.

The horizontal drive circuit 6 is configured with, for example, a shift register. The horizontal drive circuit 6 sequentially outputs horizontal scanning pulses, so that the column signal processing circuits 5 are sequentially selected and pixel signals are output from the column signal processing circuits 5 to the horizontal signal line 11.

The output circuit 7 performs signal processing on signals sequentially supplied from the column signal processing circuits 5 through the horizontal signal line 11 and outputs the signals. For example, the output circuit 7 may only perform buffering or may perform black level adjustment, column variation compensation, and various kinds of digital signal processing. An input/output terminal 13 exchanges signals with the outside of the imaging device.

The imaging device 1 configured thus is a CMOS image sensor called a column AD type sensor, in which the column signal processing circuit 5 for performing CDS processing and AD conversion is disposed for each pixel column.

The imaging device 1 is a back-illuminated MOS-type imaging device that receives light from the back side of the semiconductor substrate 12, that is, on the side opposite to the front side having pixel transistors formed thereon.

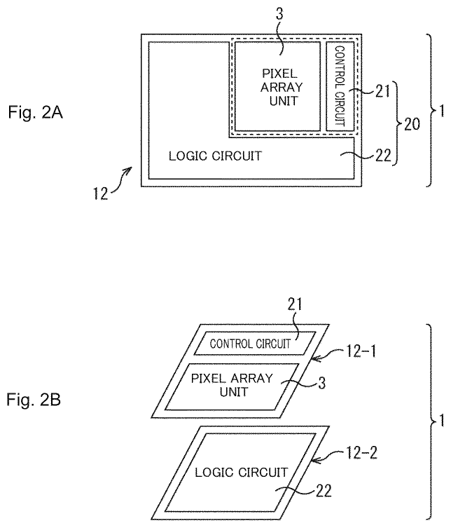

FIG. 2 illustrates a plan configuration example of the imaging device 1. A in FIG. 2 illustrates a schematic configuration example of the imaging device 1 of a non-stacked type. As illustrated in A of FIG. 2, the imaging device 1 includes the single semiconductor substrate 12. The pixel array part 3, a control circuit 21 for driving the pixels 2 and performing other kinds of control, and a logic circuit 22 for performing signal processing are mounted on the semiconductor substrate 12.

The control circuit 21 and the logic circuit 22 are provided around the pixel array part 3 on the semiconductor substrate 12. Hereinafter, the control circuit 21 and the logic circuit 22 provided around the pixel array part 3 will be collectively referred to as a pixel peripheral part 20 as appropriate.

The stacked imaging device 1 illustrated in B of FIG. 2 includes two semiconductor substrates: a semiconductor substrate 12-1 and a semiconductor substrate 12-2 that are stacked, are electrically connected to each other, and are configured as one semiconductor chip.

In B of FIG. 2, the pixel array part 3 and the control circuit 21 are mounted on the semiconductor substrate 12-1 while the logic circuit 22 including a signal processing circuit for performing signal processing is mounted on the semiconductor substrate 12-2. In the case of this configuration, the control circuit 21 is disposed around the pixel array part 3, so that the control circuit 21 constitutes the pixel peripheral part 20.

### First Embodiment

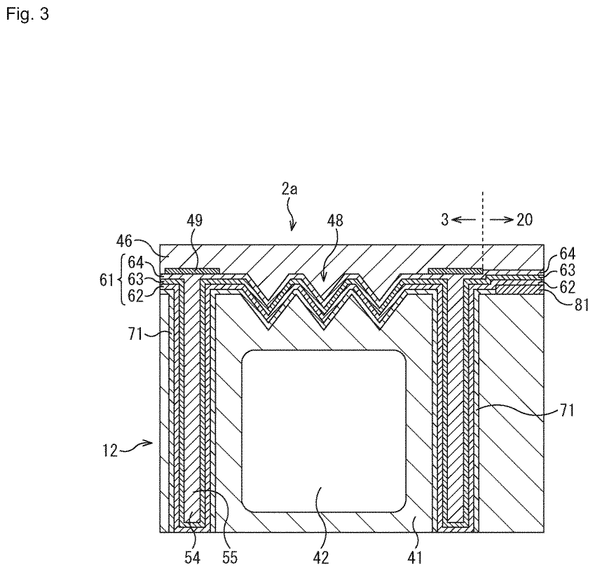

FIG. 3 illustrates an exemplary sectional configuration of a pixel 2a according to a first embodiment. FIG. 3 illustrates the configuration of the pixel 2a disposed in the array of the pixel array part 3 and the pixel peripheral part 20. The left side of FIG. 3 illustrates the pixel 2a of the pixel array part 3, and the right side of FIG. 3 illustrates the pixel peripheral part 20.

The imaging device 1 includes the semiconductor substrate 12 and a multilayer wiring layer and a support substrate (both of them are not illustrated) that are formed on the front side of the semiconductor substrate 12. The semiconductor substrate 12 is made of silicon (Si), for example. In the semiconductor substrate 12, for example, an N-type semiconductor region 42 containing an N-type impurity (second impurity) is formed for each pixel 2a in a P-type semiconductor region 41 containing a P-type impurity (first impurity), so that a photodiode PD (photoelectric conversion region) is formed for each pixel. The P-type semiconductor region 41 provided on the front and back sides of the semiconductor substrate 12 also serves as a hole charge storage region for suppressing a dark current.

The region referred to as P-type may be replaced with an N-type region, and the region referred to as N-type may be replaced with a P-type region. Such a configuration can be implemented by reading P-type as N-type and reading N-type as P-type in the following description.

As illustrated in FIG. 3, the imaging device 1 is configured such that an anti-reflection film 61 and a transparent insulating film 46 are stacked on the semiconductor substrate 12 in which the N-type semiconductor region 42 constituting the photodiode PD is formed for each pixel 2a. The imaging device 1 may be configured such that a color filter layer or an on-chip lens, which is not illustrated, is stacked on the transparent insulating film 46.

At the interface (an interface on a light receiving surface side) of the P-type semiconductor region 41 on the upper side of the N-type semiconductor region 42 serving as a charge storage region, an uneven region 48 having a fine relief structure forms the anti-reflection film 61 that prevents reflection of incident light.

The anti-reflection film 61 has, for example, a laminated structure in which a fixed charge film and an oxide film are stacked. For example, a high-dielectric constant (High-k) thin insulating film formed according to an ALD (Atomic Layer Deposition) method can be used as the anti-reflection film 61. Specifically, hafnium oxide (HfO2), aluminum oxide (Al2O3), titanium oxide (TiO2), or strontium titan oxide (STO) or the like can be used. In the example of FIG. 3, the anti-reflection film 61 is configured such that an aluminum oxide film 62, a tantalum oxide film 63, and a silicon oxide film 64 are stacked.

A P+ type semiconductor region 71 is formed between the anti-reflection film 61 and the P-type semiconductor region 41. The P+ type semiconductor region 71 is a region having a higher P-type impurity concentration than the P-type semiconductor region 41. The P+ type semiconductor region 71 is a thin layer formed under the aluminum oxide film 62 constituting the anti-reflection film 61 in FIG. 3, and is a semiconductor layer having quite a high P-type impurity concentration. The P+ type semiconductor region 71 is formed along the anti-reflection film 61 and thus has a fine relief structure like the anti-reflection film 61.

As described above, a layer including the anti-reflection film 61 and the P+ type semiconductor region 71 is provided on the light incident surface side of the photodiode PD. In the example of FIG. 3, the anti-reflection film 61 has a three-layer structure. The anti-reflection film 61 may have two layers, one layer, or more than three layers. A layer formed on the light incident surface side of the photodiode PD has at least a configuration including at least one layer constituting the P+ type semiconductor region 71 and the anti-reflection film 61.

The provision of the P+ type semiconductor region 71 can intensify pinning on the light incident surface side, that is, on the side where the anti-reflection film 61 is formed, thereby suppressing the occurrence of white spots and dark current.

A light shielding film 49 is formed between the pixels 2a while being stacked on the anti-reflection film 61. The transparent insulating film 46 is formed over the back side (light incident surface side) of the P-type semiconductor region 41. A color filter layer may be formed on the upper side of the transparent insulating film 46 including the light shielding films 49. For example, a color filter layer of red, green, or blue may be formed for each pixel.

Inter-pixel separating portions 54 (trenches constituting the inter-pixel separating portions 54) that separate the pixels 2a in the semiconductor substrate 12 may be configured to penetrate the semiconductor substrate 12 or not to penetrate the semiconductor substrate 12.

Recessed portions formed on the uneven region 48 (hereinafter, one of a plurality of recessed portions formed on the uneven region 48 will be referred to as a recessed portion 48) is formed in a triangular shape in cross section as illustrated in FIG. 3. The recessed portion 48 is not so deep as to reach the N-type semiconductor region 42 and is formed inside of the P-type semiconductor region 41.

The recessed portion 48 is an interface between the anti-reflection film 61 and the transparent insulating film 46 and is shaped with a recess in the depth direction with respect to a plane where the light shielding film 49 is formed. Thus, the portion is referred to as a recessed portion. In other words, with respect to a reference plane, for example, the top surface of the N-type semiconductor region 42, projecting portions 248 that project upward are formed on the uneven region 48. Hereinafter, it is assumed that the plane where the light shielding film 49 is formed serves as a reference plane and the recessed portions are formed from the reference plane in the depth direction.

The provision of the recessed portion 48 can secure the optical path length of light incident on the pixel 2a. Light incident on the pixel 2a enters the N-type semiconductor region 42 (photodiode) while repeating reflection, that is, light is reflected on a side of the recessed portion 48 and then is reflected on an opposite side of the recessed portion 48. The optical path length is increased by the repeated reflection. Thus, even light having a long wavelength, for example, far-red light can be absorbed with high efficiency.

The pixel peripheral part 20 in FIG. 3 will be further described below. The anti-reflection film 61 is formed also in the pixel peripheral part 20 but is linearly shaped without recesses or projections. In the pixel peripheral part 20, a region corresponding to the P+ type semiconductor region 71 is not formed.

If the pixel peripheral part 20 is also configured with the P+ type semiconductor region 71, circuit characteristics provided in the pixel peripheral part 20 may be deteriorated. The region of the pixel peripheral part 20 is configured without the P+ type semiconductor region 71, thereby preventing deterioration of circuit characteristics formed in the pixel peripheral part 20.

The provision of the P+ type semiconductor region 71 in the uneven region 48 of the pixel 2a can intensify pinning, thereby suppressing the occurrence of white spots and dark current. In contrast, the pixel peripheral part 20 is configured without the P+ type semiconductor region 71, thereby preventing deterioration of circuit characteristics.

### First Manufacturing Process of Pixel

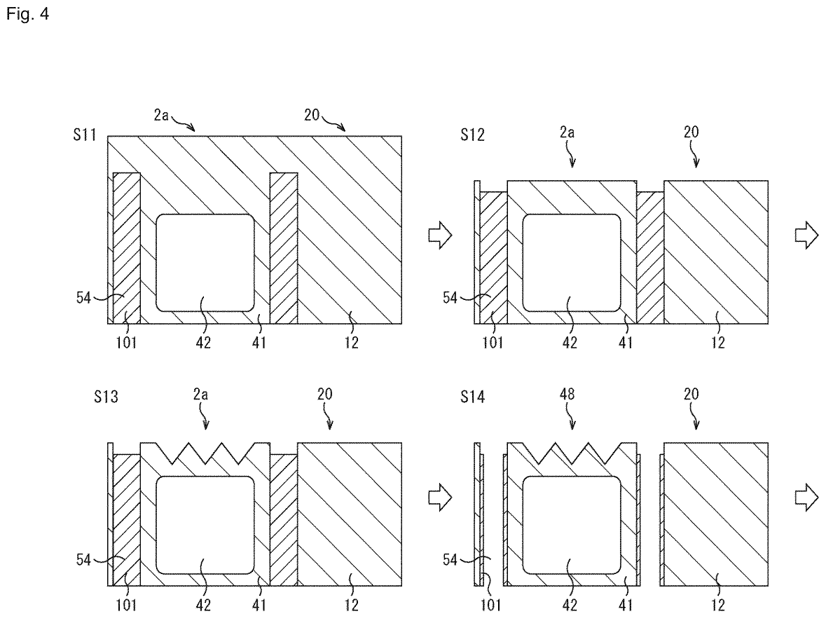

Referring to FIGS. 4 to 6, a first manufacturing process of the pixel 2a in FIG. 3 will be described below.

In step S11, the semiconductor substrate 12 is prepared such that the N-type semiconductor region 42 is formed in the P-type semiconductor region 41 of the semiconductor substrate 12 and the trenches of regions serving as the inter-pixel separating portions 54 are filled with an oxide film 101.

In step S12, the thickness of the semiconductor substrate 12 is reduced. When the thickness is reduced, the portions of the oxide film 101 are recessed according to a difference in selection ratio.

In step S13, the uneven region 48 is formed. In the uneven region 48, for example, a hard mask is formed, is processed by dry etching for opening portions to be recessed, and is subjected to alkaline wet processing, so that the recessed portions are formed. At this point, processing is performed such that the uneven region 48 is formed in the region of the pixel array part 3 but is not formed in the pixel peripheral part 20.

In step S14, the oxide film 101 in the trenches serving as the inter-pixel separating portions 54 is removed. At this point, the oxide film 101 is partially left on the side walls of the trenches as a protective film for the trenches.

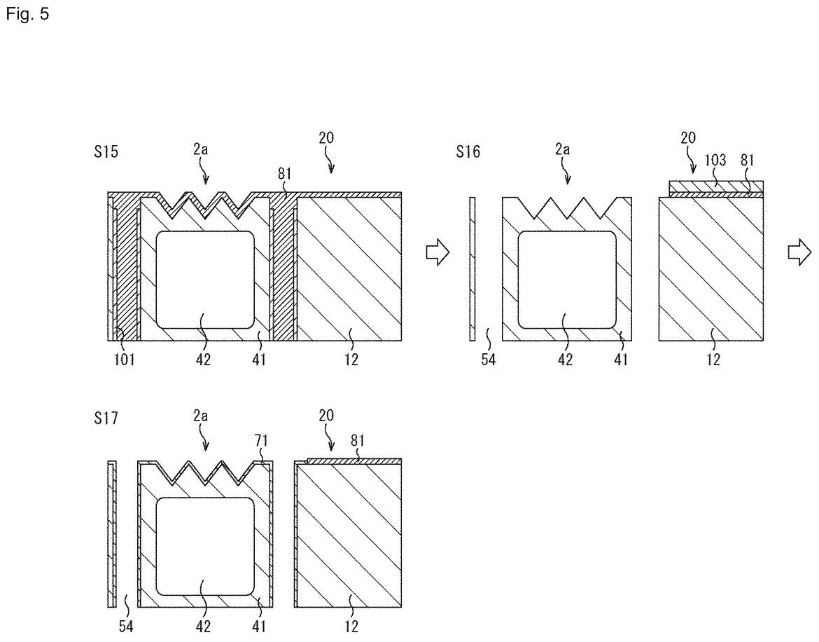

In step S15 (FIG. 5), a SiO2 film 81 is formed on the semiconductor substrate 12. The SiO2 film 81 also fills the trenches serving as the inter-pixel separating portions 54.

In step S16, a resist 103 is formed on the SiO2 film 81 formed in the pixel peripheral part 20. After the resist 103 is formed, the SiO2 film 81 is removed in a region other than the region where the resist 103 is formed.

In other words, the SiO2 film 81 formed in the pixel array part 3 is removed. The SiO2 film 81 in the trenches serving as the inter-pixel separating portions 54 and the partially left oxide film 101 are also removed. The resist 103 is removed after the SiO2 film 81 is removed.

In step S17, the P+ type semiconductor region 71 is formed. The P+ type semiconductor region 71 is formed on condition, under which the P+ type semiconductor region 71 is not selectively grown on the oxide film (SiO2 film 81), allowing processing such that the P+ type semiconductor region 71 is formed on the uneven region 48 but is not formed on the SiO2 film 81. The P+ type semiconductor region 71 is also formed on the side walls of the trenches serving as the inter-pixel separating portions 54.

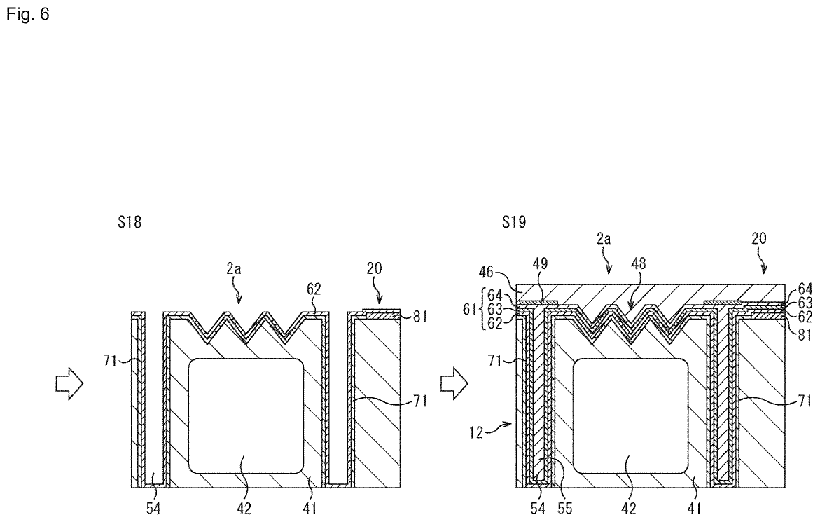

In step S18 (FIG. 6), the aluminum oxide film 62 is formed. The aluminum oxide film 62 is formed on the P+ type semiconductor region 71 formed on the uneven region 48, the SiO2 film 81 of the pixel peripheral part 20, and the side walls of the trenches serving as the inter-pixel separating portions 54.

In step S19, the tantalum oxide film 63 is formed on the aluminum oxide film 62. The silicon oxide film 64 is formed on the tantalum oxide film 63. Thus, the anti-reflection film 61 is formed.

The silicon oxide film 64 also fills the trenches serving as the inter-pixel separating portions 54. The transparent insulating film 46 is formed after the light shielding film 49 is formed on the inter-pixel separating portion 54, so that the imaging device 1 is manufactured with the pixel 2a and the pixel peripheral part 20 that have a structure illustrated in FIG. 3.

### Second Manufacturing Process of Pixel

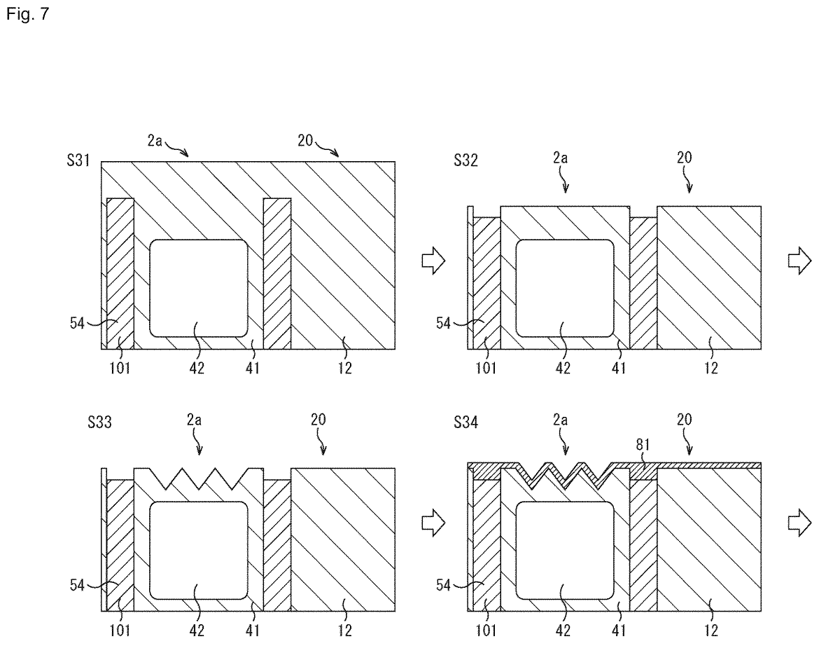

Referring to FIGS. 7 to 9, a second manufacturing process of the pixel 2a in FIG. 3 will be described below.

In step S31, the semiconductor substrate 12 is prepared such that the N-type semiconductor region 42 is formed in the P-type semiconductor region 41 of the semiconductor substrate 12 and regions serving as the inter-pixel separating portions 54 are filled with the oxide film 101. In step S32, the thickness of the semiconductor substrate 12 is reduced. In step S33, the uneven region 48 is formed. Steps S31 to S33 are performed as steps S11 to S13 (FIG. 4).

In step S34, the SiO2 film 81 is formed on the semiconductor substrate 12. Since the SiO2 film 81 is formed while the inter-pixel separating portions 54 are filled with the oxide film 101, the SiO2 film 81 is also formed on the oxide film 101.

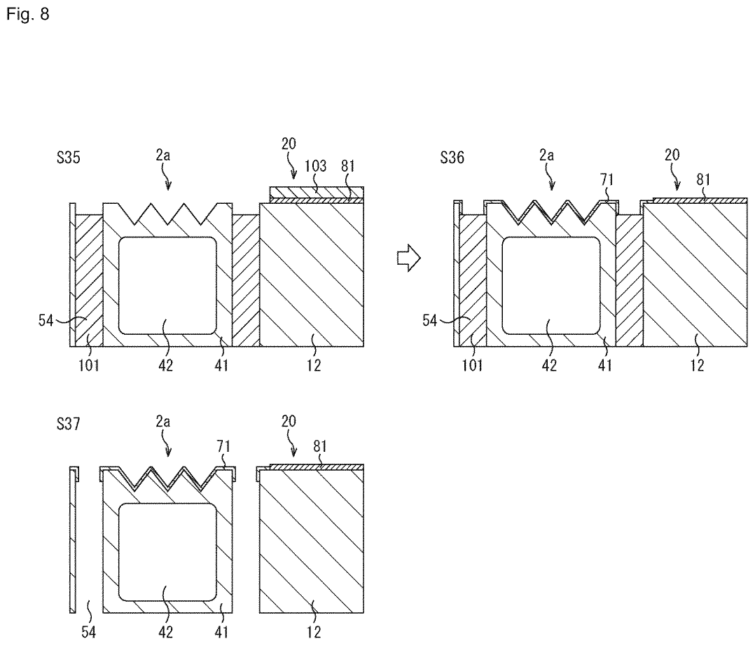

In step S35 (FIG. 8), the resist 103 is formed on the SiO2 film 81 formed in the pixel peripheral part 20. The SiO2 film 81 formed in a region other than a region where the resist 103 is formed, that is, the SiO2 film 81 formed in the region of the pixel array part 3 is removed. After the SiO2 film 81 is removed, the resist 103 is also removed.

In step S36, the P+ type semiconductor region 71 is formed. The P+ type semiconductor region 71 is formed on condition, under which the P+ type semiconductor region 71 is not selectively grown on the oxide film 101, so that the P+ type semiconductor region 71 is formed on the uneven region 48 but is not formed on the oxide film 101.

Since the P+ type semiconductor region 71 is not formed on the SiO2 film 81 as well, the P+ type semiconductor region 71 can be prevented from being formed in the pixel peripheral part 20. The inter-pixel separating portions 54 are filled with the oxide film 101, so that the P+ type semiconductor region 71 is formed on the side walls where the oxide film 101 is absent (portions where the oxide film 101 has been removed by recessing when the thickness is reduced) among the side walls in the trenches of the inter-pixel separating portions 54.

In step S37, the oxide film 101 in the regions (trenches) serving as the inter-pixel separating portions 54 is removed. According to the second manufacturing process, the P+ type semiconductor region 71 is formed only parts of the side walls of the trenches.

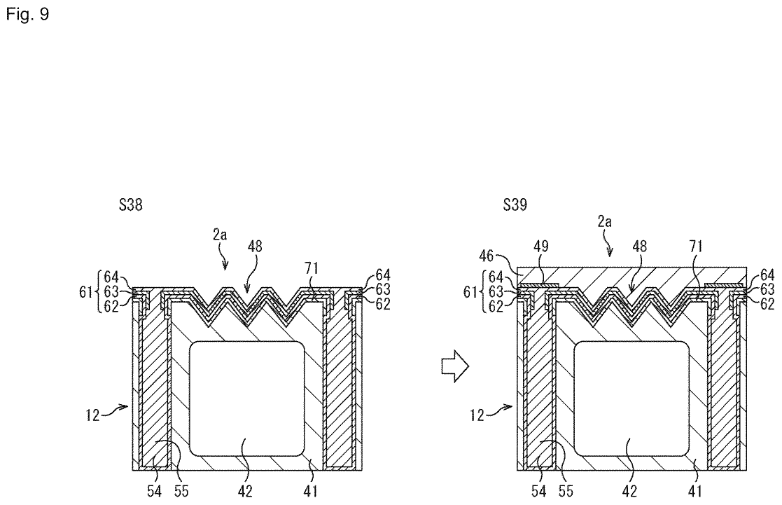

In step S38 (FIG. 9), the aluminum oxide film 62 is formed. The aluminum oxide film 62 is formed on the P+ type semiconductor region 71 formed on the uneven region 48, the SiO2 film 81 of the pixel peripheral part 20, and the side walls of the trenches serving as the inter-pixel separating portions 54.

The tantalum oxide film 63 is formed on the aluminum oxide film 62. The silicon oxide film 64 is formed on the tantalum oxide film 63. Thus, the anti-reflection film 61 is formed. The silicon oxide film 64 also fills the trenches serving as the inter-pixel separating portions 54.

In step S39, the light shielding film 49 is formed on the inter-pixel separating portion 54. The transparent insulating film 46 is formed after the light shielding film 49 is formed, so that the imaging device 1 is manufactured with the pixel 2a and the pixel peripheral part 20 that have a structure illustrated in FIG. 3.

However, the pixel 2a manufactured by the second manufacturing process is configured such that the P+ type semiconductor region 71 is formed only parts of the side walls of the inter-pixel separating portions 54 as illustrated in step S39 of FIG. 9.

Also in such a configuration, the provision of the P+ type semiconductor region 71 in the uneven region 48 of the pixel 2a can intensify pinning, thereby suppressing the occurrence of white spots and dark current. Moreover, the pixel peripheral part 20 is configured without the P+ type semiconductor region 71, thereby preventing deterioration of circuit characteristics.

### Second Embodiment

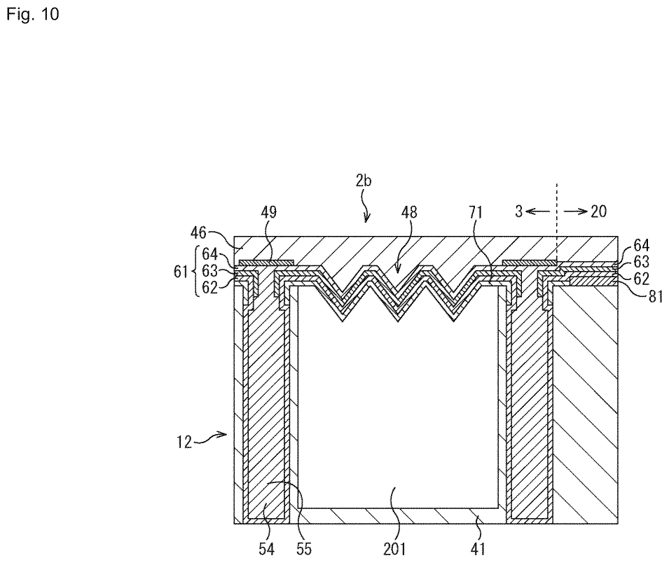

FIG. 10 illustrates an exemplary sectional configuration of a pixel 2b according to a second embodiment. In the pixel 2b illustrated in FIG. 10, the same parts as those of the pixel 2a according to the first embodiment are denoted by the same reference numerals, and descriptions thereof are omitted as appropriate. FIGS. 10 to 12 illustrate a pixel 2 manufactured according to the second manufacturing process.

The pixel 2b according to the second embodiment illustrated in FIG. 10 is different from the pixel 2a according to the first embodiment illustrated in FIG. 3 in that an N-type semiconductor region 201 constituting a photoelectric conversion region is formed to an uneven region 48. Parts other than these are identical to those in the first embodiment.

Referring to FIG. 3 again, the pixels 2a according to the first embodiment is configured such that the N-type semiconductor region 42 is surrounded by the P-type semiconductor region 41 and the uneven region 48 is formed on the P-type semiconductor region 41.

The pixel 2b according to the second embodiment illustrated in FIG. 10 is configured such that the P-type semiconductor region 41 is not provided on one side, where there is the uneven region 48, of an N-type semiconductor region 42 and, in this figure, three sides thereof, i.e., the left side, the right side, and the bottom side are surrounded by the P-type semiconductor region 41. The uneven region 48 is formed on the N-type semiconductor region 42.

The pixel 2b includes a P+ type semiconductor region 71 between an anti-reflection film 61 and the N-type semiconductor region 42. Also in the pixel 2b, the P+ type semiconductor region 71 is not formed in a pixel peripheral part 20.

The provision of the P+ type semiconductor region 71 in the uneven region 48 of the pixel 2b can intensify pinning, thereby suppressing the occurrence of white spots and dark current. In contrast, the pixel peripheral part 20 is configured without the P+ type semiconductor region 71, thereby preventing deterioration of circuit characteristics.

The pixel 2b according to the second embodiment can be manufactured by applying the first manufacturing process or the second manufacturing process. The second embodiment is different in the step of preparing a semiconductor substrate 12 such that the N-type semiconductor region 201 in the semiconductor substrate 12 is formed to a region serving as the uneven region 48 in step S11 (FIG. 4) in the application of the first manufacturing process and step S31 (FIG. 7) in the application of the second manufacturing process. The subsequent steps can be similarly performed to manufacture the pixel 2b.

### Third Embodiment

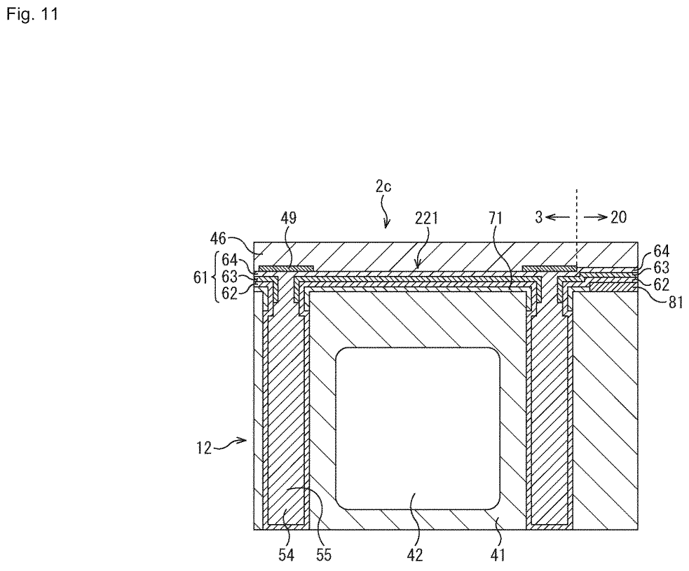

FIG. 11 illustrates an exemplary sectional configuration of a pixel 2c according to a third embodiment. In the pixel 2c illustrated in FIG. 11, the same parts as those of the pixel 2a according to the first embodiment are denoted by the same reference numerals, and descriptions thereof are omitted as appropriate.

The pixel 2c according to the third embodiment illustrated in FIG. 11 is different from the pixel 2a according to the first embodiment illustrated in FIG. 3 in that the shape of an anti-reflection film 61 is formed in a flat region 221 that is flattened in shape instead of an uneven region 48 that is irregularly shaped. Other parts are identical to those of the first embodiment.

Referring to FIG. 3 again, the pixel 2a according to the first embodiment includes the anti-reflection film 61 that is irregularly shaped in the uneven region 48. The pixel 2c according to the third embodiment illustrated in FIG. 11 includes the anti-reflection film 61 that is flattened in shape (linearly shaped) in the flat region 221.

The pixel 2c includes a P+ type semiconductor region 71 between the anti-reflection film 61 and a P-type semiconductor region 41. Also in the pixel 2c, the P+ type semiconductor region 71 is not formed in a pixel peripheral part 20.

The provision of the P+ type semiconductor region 71 between the anti-reflection film 61 and the P-type semiconductor region 41 of the pixel 2c can intensify pinning, thereby suppressing the occurrence of white spots and dark current. In contrast, the pixel peripheral part 20 is configured without the P+ type semiconductor region 71, thereby preventing deterioration of circuit characteristics.

The pixel 2c according to the third embodiment can be manufactured by applying the first manufacturing process or the second manufacturing process. The third embodiment is different in that the step of forming the uneven region 48 is omitted in step S13 (FIG. 4) in the application of the first manufacturing process and step S33 (FIG. 7) in the application of the second manufacturing process. Other steps can be similarly performed to manufacture the pixel 2c.

### Fourth Embodiment

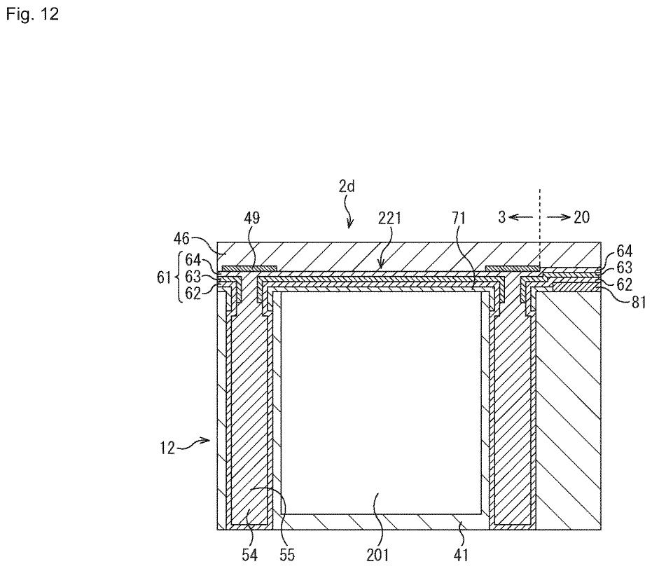

FIG. 12 illustrates an exemplary sectional configuration of a pixel 2d according to a fourth embodiment. In the pixel 2d illustrated in FIG. 12, the same parts as those of the pixel 2c according to the third embodiment illustrated in FIG. 11 are denoted by the same reference numerals, and descriptions thereof are omitted as appropriate.

The pixel 2d according to the fourth embodiment illustrated in FIG. 12 is different from the pixel 2c according to the third embodiment illustrated in FIG. 11 in that an N-type semiconductor region 201 constituting a photoelectric conversion region is formed to a flat region 221. Parts other than these are identical to those in the third embodiment.

Referring to FIG. 11 again, the pixel 2c according to the third embodiment is configured such that the N-type semiconductor region 42 is surrounded by the P-type semiconductor region 41 and the anti-reflection film 61 formed in the flat region 221 is formed in the P-type semiconductor region 41.

The pixel 2d according to the fourth embodiment illustrated in FIG. 12 is configured such that a P-type semiconductor region 41 is not provided on one side, where there is the flat region 221, of an N-type semiconductor region 42 and three sides thereof, i.e., the left side, the right side, and the bottom side are surrounded by the P-type semiconductor region 41. An anti-reflection film 61 formed in the flat region 221 is formed on the N-type semiconductor region 201.

The pixel 2d includes a P+ type semiconductor region 71 between the anti-reflection film 61 and the N-type semiconductor region 42. Also in the pixel 2d, the P+ type semiconductor region 71 is not formed in a pixel peripheral part 20.

The provision of the P+ type semiconductor region 71 between the anti-reflection film 61 and the P-type semiconductor region 41 of the pixel 2d can intensify pinning, thereby suppressing the occurrence of white spots and dark current. In contrast, the pixel peripheral part 20 is configured without the P+ type semiconductor region 71, thereby preventing deterioration of circuit characteristics.

The pixel 2d according to the fourth embodiment can be manufactured by applying the first manufacturing process or the second manufacturing process. In step S11 (FIG. 4) in the application of the first manufacturing process and step S31 (FIG. 7) in the application of the second manufacturing process, a semiconductor substrate 12 is prepared such that the N-type semiconductor region 201 in the semiconductor substrate 12 is formed to a region serving as the flat region 221. Moreover, in step S13 (FIG. 4) in the application of the first manufacturing process and step S33 (FIG. 7) in the application of the second manufacturing process, the step of forming the uneven region 48 is omitted. Other steps can be similarly performed to manufacture the pixel 2d.

### Fifth Embodiment

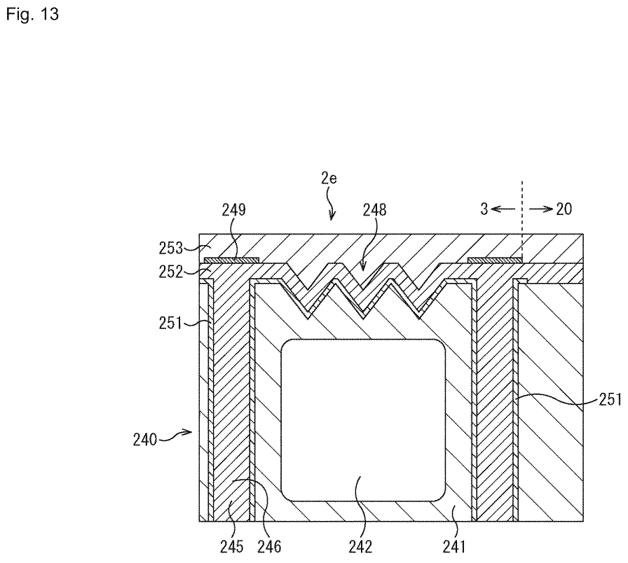

FIG. 13 illustrates an exemplary sectional configuration of a pixel 2e according to a fifth embodiment. FIG. 13 illustrates the configuration of the pixel 2e disposed in the array of a pixel array part 3 and a pixel peripheral part 20. The left side of FIG. 13 illustrates the pixel 2e of the pixel array part 3, and the right side of FIG. 13 illustrates the pixel peripheral part 20.

A semiconductor substrate 240 is made of silicon (Si), for example. In the semiconductor substrate 240, for example, an N-type semiconductor region 242 is formed for each pixel 2e in a P-type semiconductor region 241, so that a photodiode PD (photoelectric conversion region) is formed for each pixel. The P-type semiconductor region 241 provided on the front and back sides of the semiconductor substrate 240 also serves as a hole charge storage region for suppressing a dark current.

As illustrated in FIG. 13, an imaging device 1 is configured such that a P+ type semiconductor region 251, a silicon oxide film 252, and a transparent insulating film 253 are stacked on the semiconductor substrate 240 in which the N-type semiconductor region 242 constituting the photodiode PD is formed for each pixel 2e.

At the interface (an interface on a light receiving surface side) of the P-type semiconductor region 241 on the upper side of the N-type semiconductor region 242 serving as a charge storage region, the silicon oxide film 252 having a fine relief structure is formed and acts as an anti-reflection film that prevents reflection of incident light.

The P+ type semiconductor region 251 is formed between the silicon oxide film 252 and the P-type semiconductor region 241. The P+ type semiconductor region 251 is a region having a higher P-type impurity concentration than the P-type semiconductor region 241. The P+ type semiconductor region 251 is a thin layer formed under the silicon oxide film 252 in FIG. 13 and is a semiconductor layer having quite a high P-type impurity concentration. The P+ type semiconductor region 251 is formed along the silicon oxide film 252, which is formed in an uneven region 248 having a finely irregular shape, and thus has a fine relief structure like the silicon oxide film 252.

The provision of the P+ type semiconductor region 251 can intensify pinning on the light incident surface side, that is, on the side where the silicon oxide film 252 is formed, thereby suppressing the occurrence of white spots and dark current.

A light shielding film 249 is formed between the pixels 2e while being stacked on the silicon oxide film 252. The transparent insulating film 253 is formed over the back side (light incident surface) of the P-type semiconductor region 241. A color filter layer may be formed on the upper side of the transparent insulating film 253 including the light shielding films 249. For example, a color filter layer of red, green, or blue may be formed for each pixel. A configuration may be employed where a color filter layer or an on-chip lens is stacked on the color filter layer.

The pixel 2e in FIG. 13 has inter-pixel separating portions 245 that separate the pixels 2e in the semiconductor substrate 240, and. he inter-pixel separating portions 245 (the trenches constituting the inter-pixel separating portions 245) may be configured to penetrate the semiconductor substrate 240 or not to penetrate the semiconductor substrate 240.

The pixel 2e in FIG. 13 includes the silicon oxide film 252 as an anti-reflection film. The pixel 2a according to the first embodiment illustrated in FIG. 3 is configured such that the aluminum oxide film 62, the tantalum oxide film 63, and the silicon oxide film 64 are stacked as the anti-reflection film 61.

The aluminum oxide film 62 may be damaged by UV (ultraviolet) light, which may suppress the function of a pinning film. The tantalum oxide film 63 may absorb light in the wave range of UV light, which may reduce light reaching the photodiode PD. Thus, if the imaging device 1 is applied to a UV light sensor or the like, device characteristics such as dark current may be deteriorated.

The pixel 2e illustrated in FIG. 13 does not include the aluminum oxide film 62, thereby reducing damage caused by UV light. The pixel 2e does not include the tantalum oxide film 63, so that even attenuation of light in the wave range of UV light can be suppressed to transmit light to the photodiode PD. Furthermore, the pixel 2e includes the P+ type semiconductor region 251, thereby preventing deterioration of the function of pinning. Thus, in the pixel 2e, deterioration of device characteristics can be suppressed.

The pixel 2e is applicable to a UV sensor for UV light.

The pixel peripheral part 20 in FIG. 13 will be further described below. The silicon oxide film 252 is formed also in the pixel peripheral part 20 but is linearly shaped without recesses or projections. In the pixel peripheral part 20, a region corresponding to the P+ type semiconductor region 251 is not formed. If the pixel peripheral part 20 is also configured with the P+ type semiconductor region 251, circuit characteristics formed in the pixel peripheral part 20 may be deteriorated. The region of the pixel peripheral part 20 is configured without the P+ type semiconductor region 251, thereby preventing deterioration of circuit characteristics formed in the pixel peripheral part 20.

### Manufacturing of Pixel According to Fifth Embodiment

A manufacturing process of the pixel 2e illustrated in FIG. 13 will be further described below. The pixel 2e can be manufactured by applying the first manufacturing process described with reference to FIGS. 4 to 6 or the second manufacturing process described with reference to FIGS. 7 to 9.

If the pixel 2e is manufactured by applying the first manufacturing process, the P+ type semiconductor region 251 (the P+ type semiconductor region 71 in FIG. 5) is formed in step S17 (FIG. 5), and then as processing corresponding to steps S18 and S19 (FIG. 6), the silicon oxide film 252 is formed, the light shielding film 249 is formed, and the transparent insulating film 253 is formed, so that the pixel 2e is manufactured.

If the pixel 2e is manufactured by applying the second manufacturing process, the P+ type semiconductor region 251 (the P+ type semiconductor region 71 in FIG. 8) is formed in step S37 (FIG. 8), and then as processing corresponding to steps S38 and S39 (FIG. 9), the silicon oxide film 252 is formed, the light shielding film 249 is formed, and the transparent insulating film 253 is formed, so that the pixel 2e is manufactured.

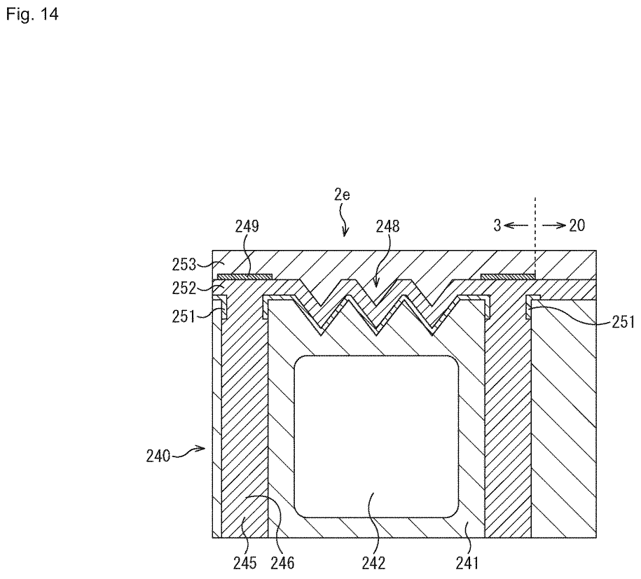

If the pixel 2e is manufactured by applying the second manufacturing process, as illustrated in FIG. 14, the P+ type semiconductor region 251 is formed only on parts of the side wall of the inter-pixel separating portions 245, that is, only on the upper side in FIG. 14.

Also in the configuration of the pixel 2e illustrated in FIG. 14, the provision of the P+ type semiconductor region 251 in the uneven region 248 of the pixel 2e can intensify pinning, thereby suppressing the occurrence of white spots and dark current. Moreover, the pixel peripheral part 20 is configured without the P+ type semiconductor region 251, thereby preventing deterioration of circuit characteristics.

### Sixth Embodiment

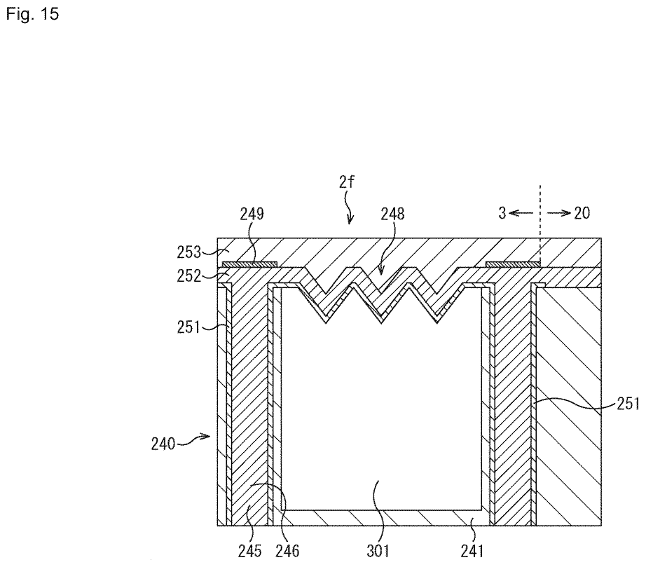

FIG. 15 illustrates an exemplary sectional configuration of a pixel 2f according to a sixth embodiment. In the pixel 2f illustrated in FIG. 15, the same parts as those of the pixel 2e (FIG. 13) according to the fifth embodiment are denoted by the same reference numerals, and descriptions thereof are omitted as appropriate.

The pixel 2f according to the sixth embodiment illustrated in FIG. 15 is different from the pixel 2e according to the fifth embodiment illustrated in FIG. 13 in that an N-type semiconductor region 301 constituting a photoelectric conversion region is formed to an uneven region 248. Parts other than these are identical to those in the fifth embodiment.

Referring to FIG. 13 again, the pixel 2e according to the fifth embodiment is configured such that the N-type semiconductor region 242 is surrounded by the P-type semiconductor region 241 and the uneven region 248 is formed on the P-type semiconductor region 241.

The pixel 2f according to the sixth embodiment illustrated in FIG. 15 is configured such that a P-type semiconductor region 241 is not provided on one side, where there is the uneven region 248, of an N-type semiconductor region 242 and three sides thereof, i.e., the left side, the right side, and the bottom side are surrounded by the P-type semiconductor region 241. The uneven region 248 is formed on the N-type semiconductor region 242.

The pixel 2f includes a P+ type semiconductor region 251 between a silicon oxide film 252 and the N-type semiconductor region 301. Also in the pixel 2f, the P+ type semiconductor region 251 is not formed in a pixel peripheral part 20.

The provision of the P+ type semiconductor region 251 in the uneven region 248 of the pixel 2f can intensify pinning, thereby suppressing the occurrence of white spots and dark current. In contrast, the pixel peripheral part 20 is configured without the P+ type semiconductor region 251, thereby preventing deterioration of circuit characteristics.

### Seventh Embodiment

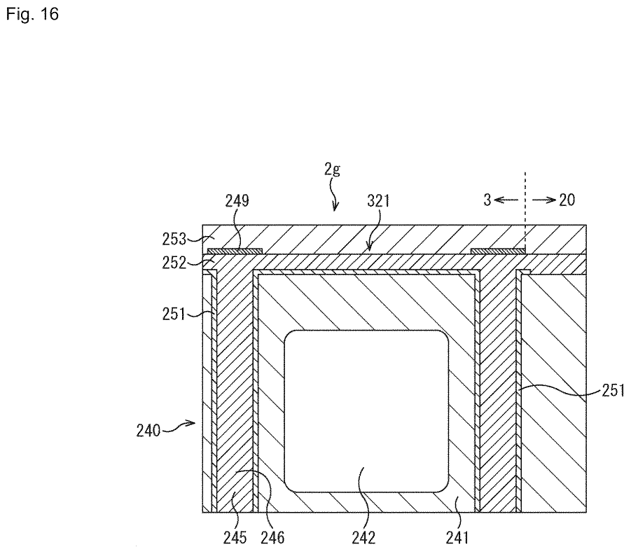

FIG. 16 illustrates an exemplary sectional configuration of a pixel 2g according to a seventh embodiment. In the pixel 2g illustrated in FIG. 16, the same parts as those of the pixel 2e (FIG. 13) according to the fifth embodiment are denoted by the same reference numerals, and descriptions thereof are omitted as appropriate.

The pixel 2g according to the seventh embodiment illustrated in FIG. 16 is different from the pixel 2e according to the fifth embodiment illustrated in FIG. 13 in that a silicon oxide film 252 is not irregularly shaped but is formed in a flat region 321 that is flattened in shape. Other parts are identical to those of the fifth embodiment.

Referring to FIG. 13 again, the pixel 2e according to the fifth embodiment includes the silicon oxide film 252 that is irregularly shaped in the uneven region 248. The pixel 2g according to the seventh embodiment illustrated in FIG. 16 includes the silicon oxide film 252 that is flattened in shape (linearly shaped) in the flat region 321.

The pixel 2g includes a P+ type semiconductor region 251 between the silicon oxide film 252 and a P-type semiconductor region 241. Also in the pixel 2g, the P+ type semiconductor region 251 is not formed in a pixel peripheral part 20.

The provision of the P+ type semiconductor region 251 between the silicon oxide film 252 and the P-type semiconductor region 241 of the pixel 2g can intensify pinning, thereby suppressing the occurrence of white spots and dark current. In contrast, the pixel peripheral part 20 is configured without the P+ type semiconductor region 251, thereby preventing deterioration of circuit characteristics.

### Eighth Embodiment

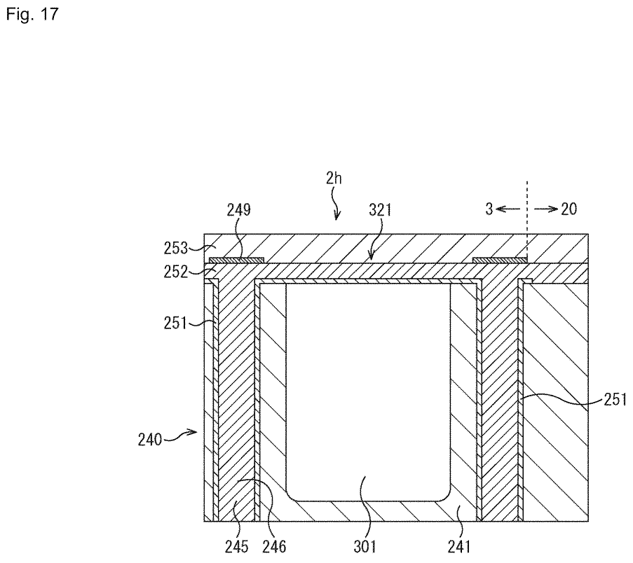

FIG. 17 illustrates an exemplary sectional configuration of a pixel 2h according to an eighth embodiment. In the pixel 2h illustrated in FIG. 17, the same parts as those of the pixel 2g according to the seventh embodiment illustrated in FIG. 16 are denoted by the same reference numerals, and descriptions thereof are omitted as appropriate.

The pixel 2h according to the eighth embodiment illustrated in FIG. 17 is different from the pixel 2g according to the seventh embodiment illustrated in FIG. 16 in that an N-type semiconductor region 301 constituting a photoelectric conversion region is formed to a flat region 321. Parts other than these are identical to those in the seventh embodiment.

Referring to FIG. 16 again, the pixel 2g according to the seventh embodiment is configured such that the N-type semiconductor region 242 is surrounded by the P-type semiconductor region 241 and the flat region 321 is formed on the P-type semiconductor region 241.

The pixel 2h according to the eighth embodiment illustrated in FIG. 17 is configured such that a P-type semiconductor region 241 is not provided on one side, where there is the flat region 321, of the N-type semiconductor region 301 and three sides thereof, i.e., the left side, the right side, and the bottom side are surrounded by the P-type semiconductor region 241. A silicon oxide film 252 formed in the flat region 321 is formed on an N-type semiconductor region 242.

The pixel 2h includes a P+ type semiconductor region 251 between the silicon oxide film 252 and the N-type semiconductor region 42. Also in the pixel 2h, the P+ type semiconductor region 251 is not formed in a pixel peripheral part 20.

The provision of the P+ type semiconductor region 251 between the silicon oxide film 252 and the P-type semiconductor region 241 of the pixel 2h can intensify pinning, thereby suppressing the occurrence of white spots and dark current. In contrast, the pixel peripheral part 20 is configured without the P+ type semiconductor region 251, thereby preventing deterioration of circuit characteristics.

### Example of Application to Electronic Device

The present technique is not limited to an application to an imaging element. In other words, the present technique can be generally applied to electronic devices using imaging elements for image capturing units (photoelectric conversion units), for example, imaging devices such as a digital still camera and a video camera, a mobile terminal device having an imaging function, and a copying machine using an imaging element in an image reading unit. The imaging element may be formed as one chip or may be formed as a module in which an imaging unit and a signal processing unit or an optical system are collectively packaged with an imaging function.

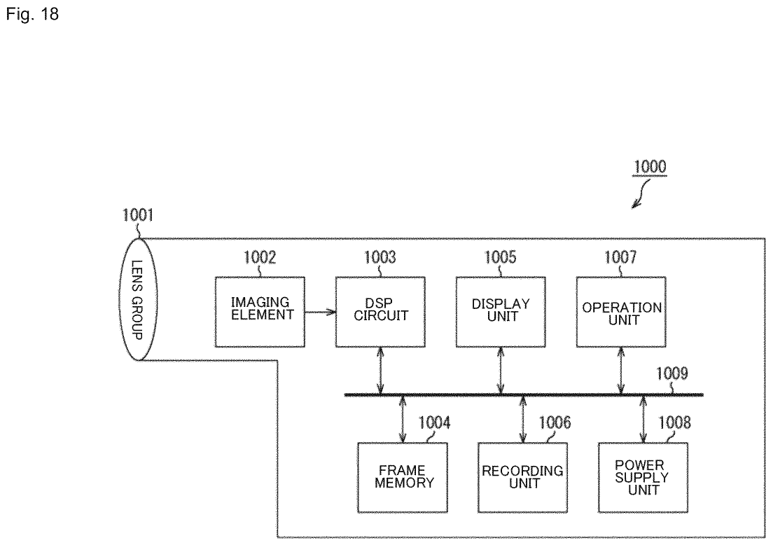

FIG. 18 is a block diagram illustrating a configuration example of an imaging device as an electronic device to which the present technique is applied.

An imaging element 1000 in FIG. 18 includes an optical unit 1001 including a lens group, an imaging element (imaging device) 1002 in which the configuration of the imaging device 1 in FIG. 1 is adopted, and a DSP (Digital Signal Processor) circuit 1003 serving as a camera signal processing circuit. The imaging element 1000 also includes a frame memory 1004, a display unit 1005, a recording unit 1006, an operation unit 1007, and a power supply unit 1008. The DSP circuit 1003, the frame memory 1004, the display unit 1005, the recording unit 1006, the operation unit 1007, and the power supply unit 1008 are connected to one another via a bus line 1009.

The optical unit 1001 captures incident light (image light) from a subject and forms an image on an imaging surface of the imaging element 1002. The imaging element 1002 converts an amount of incident light, which is imaged on the imaging surface by the optical unit 1001, into an electrical signal for each pixel and outputs the electrical signal as a pixel signal. The imaging device 1 in FIG. 1 can be used as the imaging element 1002.

The display unit 1005 is configured with, for example, a thin display such as an LCD (Liquid Crystal Display) or an organic EL (Electro Luminescence) display and displays a moving image or a still image captured by the imaging element 1002. The recording unit 1006 records a moving image or a still image captured by the imaging element 1002, in a recording medium such as a hard disk or a semiconductor memory.

The operation unit 1007 provides operation instructions on various functions of the imaging element 1000 in response to a user operation. The power supply unit 1008 supplies various kinds of power supplies as operation power supplies to the targets of supply, that is, the DSP circuit 1003, the frame memory 1004, the display unit 1005, the recording unit 1006, and the operation unit 1007.

### Example of Application to Mobile Object

The technique of the present disclosure (the present technique) can be applied to various products. For example, the technique according to the present disclosure may be implemented as a device mounted on any type of mobile object such as an automobile, an electric automobile, a hybrid electric automobile, a motorcycle, a bicycle, a personal mobility device, an airplane, a drone, a ship, a robot, or the like.

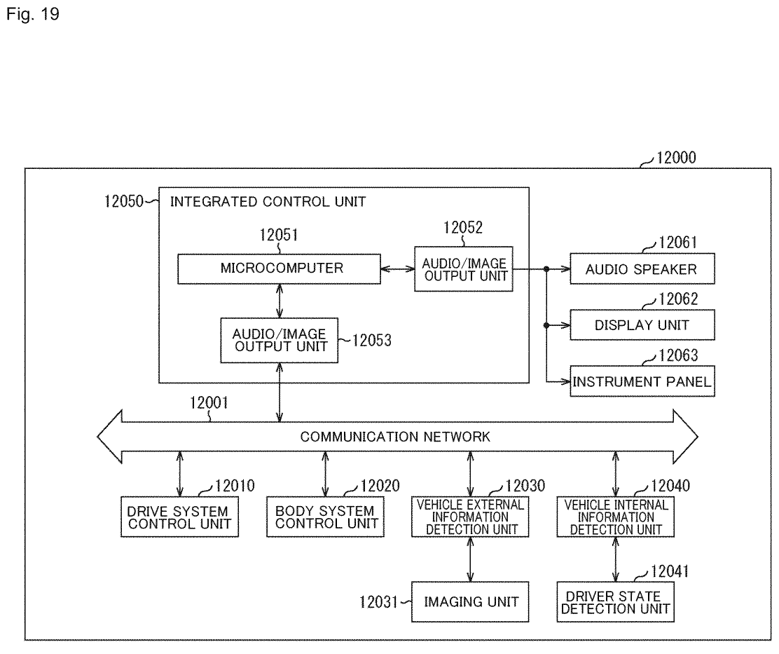

FIG. 19 is a block diagram illustrating a schematic configuration example of a vehicle control system, which is an example of a mobile object control system to which the technique according to the present disclosure is applicable.

The vehicle control system 12000 includes a plurality of electronic control units connected via a communication network 12001. In the example illustrated in FIG. 19, the vehicle control system 12000 includes a drive system control unit 12010, a body system control unit 12020, a vehicle external information detection unit 12030, a vehicle internal information detection unit 12040, and an integrated control unit 12050. As a functional configuration of the integrated control unit 12050, a microcomputer 12051, an audio/image output unit 12052, and an in-vehicle network I/F (interface) 12053 are illustrated.

The drive system control unit 12010 controls an operation of an apparatus related to a drive system of a vehicle according to various programs. For example, the drive system control unit 12010 functions as a driving force generator for generating a driving force of a vehicle such as an internal combustion engine or a driving motor, a driving force transmission mechanism for transmitting a driving force to wheels, a steering mechanism for adjusting a turning angle of a vehicle, and a control apparatus such as a braking apparatus that generates a braking force of a vehicle.

The body system control unit 12020 controls operations of various devices mounted in the vehicle body according to various programs. For example, the body system control unit 12020 functions as a control device of a keyless entry system, a smart key system, a power window device, or various lamps such as a headlamp, a back lamp, a brake lamp, a turn signal, and a fog lamp. In this case, radio waves transmitted from a portable device that substitutes for a key or signals of various switches may be input to the body system control unit 12020. The body system control unit 12020 receives inputs of the radio waves or signals and controls a door lock device, a power window device, and a lamp of the vehicle.

The vehicle external information detection unit 12030 detects information on the outside of the vehicle having the vehicle control system 12000 mounted thereon. For example, an imaging unit 12031 is connected to the vehicle external information detection unit 12030. The vehicle external information detection unit 12030 causes the imaging unit 12031 to capture an image of the outside of the vehicle and receives the captured image. The vehicle external information detection unit 12030 may perform object detection processing or distance detection processing for persons, cars, obstacles, signs, and letters on the road on the basis of the received image.

The imaging unit 12031 is an optical sensor that receives light and outputs an electrical signal according to the amount of the received light. The imaging unit 12031 can also output the electrical signal as an image or distance measurement information. In addition, the light received by the imaging unit 12031 may be visible light or invisible light such as infrared light.

The vehicle internal information detection unit 12040 detects information on the inside of the vehicle. For example, a driver state detection unit 12041 that detects a driver's state is connected to the vehicle internal information detection unit 12040. The driver state detection unit 12041 includes, for example, a camera that captures an image of a driver, and the vehicle internal information detection unit 12040 may calculate a degree of fatigue or concentration of the driver or may determine whether or not the driver is dozing on the basis of detection information input from the driver state detection unit 12041.

The microcomputer 12051 can calculate control target values for the driving force generation device, the steering mechanism, or the braking device on the basis of information on the inside and outside of the vehicle, the information being acquired by the vehicle external information detection unit 12030 or the vehicle internal information detection unit 12040, and the microcomputer 12051 can output control commands to the drive system control unit 12010. For example, the microcomputer 12051 can perform cooperative control for the purpose of implementing the functions of an ADAS (Advanced Driver Assistance System) including vehicle collision avoidance, impact mitigation, following traveling based on an inter-vehicle distance, vehicle speed maintenance driving, vehicle collision warning, and vehicle lane deviation warning.

Furthermore, the microcomputer 12051 can perform cooperative control for the purpose of automated driving or the like in which autonomous driving is performed without operations of the driver, by controlling the driving force generator, the steering mechanism, or the braking device and the like on the basis of information about the surroundings of the vehicle, the information being acquired by the vehicle external information detection unit 12030 or the vehicle internal information detection unit 12040.

In addition, the microcomputer 12051 can output a control command to the body system control unit 12030 on the basis of the information acquired outside the vehicle by the vehicle external information detection unit 12030. For example, the microcomputer 12051 can perform cooperative control for the purpose of antiglare, for example, switching a high beam to a low beam by controlling a headlamp according to a position of a vehicle ahead or an oncoming vehicle detected by the vehicle external information detection unit 12030.

The audio/image output unit 12052 transmits an output signal of at least one of sound and an image to an output device capable of visually or audibly notifying information to a passenger or the outside of the vehicle. In the example of FIG. 19, an audio speaker 12061, a display unit 12062, and an instrument panel 12063 are illustrated as examples of the output device. The display unit 12062 may include, for example, at least one of an on-board display and a head-up display.

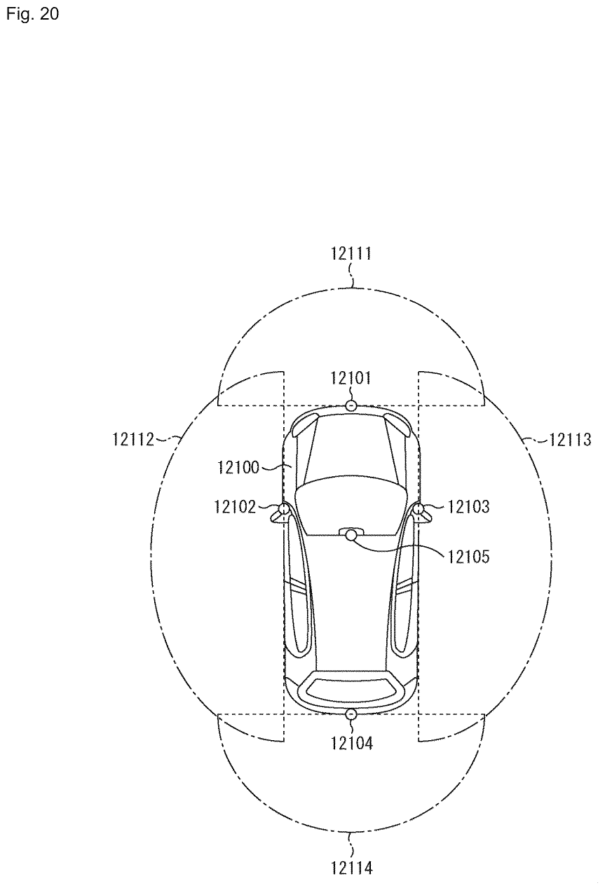

FIG. 20 illustrates an example of the installation position of the imaging unit 12031.

In FIG. 20, the imaging unit 12031 includes imaging units 12101, 12102, 12103, 12104, and 12105.

The imaging units 12101, 12102, 12103, 12104, and 12105 are provided at, for example, the positions of the front nose, side mirrors, rear bumper, back door of the vehicle 12100 and an upper portion of a windshield in the vehicle. The imaging unit 12101 provided at a front nose and the imaging unit 12105 provided in an upper portion of the windshield in the vehicle mainly acquire images ahead of the vehicle 12100. The imaging units 12102 and 12103 provided at the side mirrors mainly acquire images on the sides of the vehicle 12100. The imaging unit 12104 provided at the rear bumper or the back door mainly acquires an image of an area behind the vehicle 12100. The imaging unit 12105 provided in the upper portion of the windshield inside the vehicle is mainly used for detection of a vehicle ahead, a pedestrian, an obstacle, a traffic signal, a traffic sign, or a lane or the like.

FIG. 20 illustrates an example of the imaging ranges of the imaging units 12101 to 12104. An imaging range 12111 indicates the imaging range of the imaging unit 12101 provided at the front nose, imaging ranges 12112 and 12113 respectively indicate the imaging ranges of the imaging units 12102 and 12103 provided at the side-view mirrors, and an imaging range 12114 indicates the imaging range of the imaging unit 12104 provided at the rear bumper or the back door. For example, by superimposing image data captured by the imaging units 12101 to 12104, a bird's-eye view image of the vehicle 12100 viewed from above can be obtained.

At least one of the imaging units 12101 to 12104 may have the function of acquiring distance information. For example, at least one of the imaging units 12101 to 12104 may be a stereo camera including a plurality of imaging elements or may be an imaging element that has pixels for phase difference detection.

For example, the microcomputer 12051 can extract, in particular, a closest three-dimensional object on a traveling path of the vehicle 12100, which is a three-dimensional object traveling at a predetermined speed (for example, 0 km/h or higher) in the substantially same direction as the vehicle 12100, as a vehicle ahead by obtaining a distance to each three-dimensional object in the imaging ranges 12111 to 12114 and temporal change in the distance (a relative speed with respect to the vehicle 12100) on the basis of distance information obtained from the imaging units 12101 to 12104. The microcomputer 12051 can also set a distance to be secured from a vehicle ahead and perform automatic brake control (including following stop control) and automatic acceleration control (including following start control). Thus, cooperative control can be performed for the purpose of, for example, automated driving in which autonomous driving is performed without operations of the driver.

For example, the microcomputer 12051 can classify and extract three-dimensional data regarding three-dimensional objects into two-wheeled vehicles, ordinary vehicles, large vehicles, pedestrians, and other three-dimensional objects such as electric poles on the basis of distance information obtained from the imaging units 12101 to 12104 and can use the three-dimensional data for automated avoidance of obstacles. For example, the microcomputer 12051 classifies obstacles around the vehicle 12100 into obstacles visible to the driver of the vehicle 12100 and obstacles hardly visible to the driver. Thereafter, the microcomputer 12051 determines a collision risk indicating the degree of risk of collision with each obstacle. When the collision risk is equal to or higher than a set value and there is a possibility of collision, an alarm is output to the driver through the audio speaker 12061 or the display unit 12062 and forced deceleration or avoidance steering is performed through the drive system control unit 12010, achieving driving support for collision avoidance.

At least one of the imaging units 12101 to 12104 may be an infrared camera that detects infrared rays. For example, the microcomputer 12051 can recognize a pedestrian by determining the presence or absence of a pedestrian in captured images of the imaging units 12101 to 12104. Such pedestrian recognition is performed by, for example, the step of extracting feature points in the captured images of the imaging units 12101 to 12104 as infrared cameras and the step of pattern matching on a series of feature points indicating an outline of an object to determine whether or not the object is a pedestrian. When the microcomputer 12051 determines that a pedestrian is present in the captured images of the imaging units 12101 to 12104 and recognizes the pedestrian, the audio/image output unit 12052 controls the display unit 12062 such that a square contour line for emphasis is superimposed and displayed on the recognized pedestrian. In addition, the audio/image output unit 12052 may control the display unit 12062 such that an icon or the like indicating a pedestrian is displayed at a desired position.

The system as used herein refers to an entire device configured with a plurality of devices.

The effects described in the present specification are merely examples and are not limited, and other effects may be obtained.

Embodiments of the present technique are not limited to the above-described embodiment and various modifications can be made within the scope of the present technique without departing from the gist of the present technique.

The present technique can also be configured as follows:
(1)

An imaging device including: a photoelectric conversion region including a first semiconductor region containing a first impurity and a second semiconductor region containing a second impurity; and
a layer region including at least a first layer containing a high concentration of the first impurity and a second layer made of a predetermined material on a light incident surface side of the photoelectric conversion region.
(2)

The imaging device according to (1), further including a pixel array part including the photoelectric conversion region disposed therein in an array form; and
a pixel peripheral part including a processing unit that is disposed therein and processes a signal from the pixel array part,
wherein
the pixel peripheral part is provided with a layer region not including the first layer.
(3)

The imaging device according to (1) or (2), wherein the layer region has an irregular shape.
(4)

The imaging device according to (1) or (2), wherein the layer region has a flat shape.
(5)

The imaging device according to any one of (1) to (4), wherein the second layer is made of silicon oxide.
(6)

The imaging device according to any one of (1) to (4), wherein the layer region includes layers made of silicon oxide, aluminum oxide, and tantalum oxide, respectively.
(7)

The imaging device according to any one of (1) to (6), wherein the layer region is formed on the first semiconductor region.
(8)

The imaging device according to any one of (1) to (6), wherein the layer region is formed on the second semiconductor region.
(9)

The imaging device according to any one of (1) to (8), wherein the first impurity is an N-type impurity and the second impurity is a P-type impurity, or the first impurity is a P-type impurity and the second impurity is an N-type impurity.
(10)

An electronic device including: an imaging device; and a processing unit, the imaging device including a photoelectric conversion region including a first semiconductor region containing a first impurity and a second semiconductor region containing a second impurity, the imaging device further including
a layer region including at least a first layer containing a high concentration of the first impurity, and a second layer made of a predetermined material on a light incident surface side of the photoelectric conversion region, and the processing unit being configured to process a signal from the imaging device.

### Reference Signs List

1 Imaging device
2 Pixel
3 Pixel array part
4 Vertical drive circuit
5 Column signal processing circuit
6 Horizontal drive circuit
7 Output circuit
8 Control circuit
9 Vertical signal line
10 Pixel drive wiring
11 Horizontal signal line
12 Semiconductor substrate
13 Input/output terminal
20 Pixel peripheral unit
21 Control circuit
22 Logic circuit
41 P-type semiconductor region
42 N-type semiconductor region
46 Transparent insulating film
48 Uneven region
49 Light shielding film
54 Inter-pixel separating portion
61 Anti-reflection film
62 Aluminum oxide film
63 Tantalum oxide film
64 Silicon oxide film
71 Type semiconductor region
81 SiO2 film
101 Oxide film
103 Resist
201 N-type semiconductor region
221 Flat region
240 Semiconductor substrate
241 P-type semiconductor region
242 N-type semiconductor region
245 Inter-pixel separating portion
248 Uneven region
249 Light shielding film
251 Type semiconductor region
252 Silicon oxide film
253 Transparent insulating film
301 N-type semiconductor region
321 Flat region

1. An imaging device comprising: a photoelectric conversion region including a first semiconductor region containing a first impurity and a second semiconductor region containing a second impurity; and
a layer region including at least a first layer containing a high concentration of the first impurity and a second layer made of a predetermined material on a light incident surface side of the photoelectric conversion region.

2. The imaging device according to claim 1, further comprising a pixel array part including the photoelectric conversion region disposed therein in an array form; and
a pixel peripheral part including a processing unit that is disposed therein and processes a signal from the pixel array part,
wherein
the pixel peripheral part is provided with a layer region not including the first layer.

3. The imaging device according to claim 1, wherein the layer region has an irregular shape.

4. The imaging device according to claim 1, wherein the layer region has a flat shape.

5. The imaging device according to claim 1, wherein the second layer is made of silicon oxide.

6. The imaging device according to claim 1, wherein the layer region includes layers made of silicon oxide, aluminum oxide, and tantalum oxide, respectively.

7. The imaging device according to claim 1, wherein the layer region is formed on the first semiconductor region.

8. The imaging device according to claim 1, wherein the layer region is formed on the second semiconductor region.

9. The imaging device according to claim 1, wherein the first impurity is an N-type impurity and the second impurity is a P-type impurity, or the first impurity is a P-type impurity and the second impurity is an N-type impurity.

10. An electronic device comprising: an imaging device; and a processing unit, the imaging device including a photoelectric conversion region including a first semiconductor region containing a first impurity and a second semiconductor region containing a second impurity, the imaging device further including
a layer region including at least a first layer containing a high concentration of the first impurity and a second layer made of a predetermined material on a light incident surface side of the photoelectric conversion region, and the processing unit being configured to process a signal from the imaging device.
